(19) United States
(12) Patent Application Publication
(10) Pub. No.: US 2018/0239238 A1
(43) Pub. Date: Aug. 23, 2018

(54) MASK

(71) Applicant: BOE TECHNOLOGY GROUP CO., LTD., Beijing (CN)

(72) Inventor: Feng ZHANG, Beijing (CN)

(21) Appl. No.: 15/715,272

(22) Filed: Sep. 26, 2017

(30) Foreign Application Priority Data
Feb. 20, 2017 (CN) 201710090975.1

(51) Int. Cl. G03F 1/38

(52) U.S. Cl. CPC G03F 1/38; G03F 7/706

(57) ABSTRACT

The present disclosure provides a mask, comprising a light shielding region and a light transmitting region, wherein the mask further includes a diffraction region, and the diffraction region is disposed in the light transmission region for diffracting transmitted light.

### CROSS-REFERENCE TO RELATED APPLICATIONS

The present application claims priority to Chinese Patent Application No. 201710090975.1, titled “MASK” filed Feb. 20, 2017, the entire contents of which are incorporated herein by reference.

### TECHNICAL FIELD

The present disclosure relates to the field of lithography technology, and more particularly, to a mask.

### BACKGROUND

With the continuous progress of science and technology, visual information have become increasingly important in daily lives, and thus flat panel display devices for carrying visual information have become increasingly important. These flat panel display devices include liquid crystal display devices (LCDs), organic light emitting diodes (OLEDs), field emission displays (FEDs), plasma displays (PDPs), and the like. With the improvement of people's living standards and technological progress, people's requirement on quality of display panels is also gradually increased, for example high-resolution, high color gamut, fast response, which imposes high requirement on the manufacture technology.

With resolution of a display panel increases, sizes of wirings and vias in the display panel decreases. Moreover, due to special shape of the via (round, oval, square, etc.), for the same size, a via is more difficult to be identified than a line width. Therefore, residual photoresist may appear at a via. As a result, the via cannot be resolved, affecting the product yield.

### SUMMARY

Embodiments of the present disclosure are to provide a mask.

The present disclosure provides a mask, comprising a light shielding region and a light transmitting region, wherein the mask further comprises a diffraction region, and the diffraction region is disposed in the light transmission region for diffracting transmitted light.

In one implementation, the diffraction region comprises at least one light shielding portion and at least one light transmitting portion, and a distance between opposite sides of the light transmitting portion is 0.2 μm to 0.5 μm.

In one implementation, a width of the light shielding portion is 0.2 μm to 0.5 μm.

In one implementation, a number of the light shielding portion is one, and the light shielding portion is in a ring shape, the light shielding portion is an area surrounded by the ring-shaped light shielding portion.

In one implementation, the center of the light transmitting portion overlaps with center of the light transmitting region.

In one implementation, a number of the light shielding portion is two or more, and the light shielding portion is in a ring shape, the two or more ring-shaped light shielding portions are arranged as one surrounded by another successively, and at least one light shielding portion includes an area surrounded by the ring-shaped light shielding portion of the innermost ring and areas between two adjacent ring-shaped light shielding portions.

In one implementation, the center of the light transmitting portion surrounded by the ring-shaped light shielding portion of the innermost ring overlaps with the center of the light transmitting region.

In one implementation, two or more ring-shaped light shielding portions are arranged concentrically.

In one implementation, the ring shape is a circular ring, a square ring, a rectangular ring.

In one implementation, a number of the light shielding portion is two or more, and the light shielding portion is in a bar shape, the two or more shading portions are arranged in parallel to each other, and the light transmitting portion is an area between two adjacent light shielding portions.

In one implementation, the number of the light shielding portions is an even number and the number of the light transmitting portions is an odd number, the center of the innermost light transmitting portion overlaps with the center of the light transmitting region.

In one implementation, a distance between the edge of the light transmitting region and the adjacent light shielding portion is 1 μm to 2 μm.

### BRIEF DESCRIPTION OF THE DRAWINGS

In order to more clearly illustrate the technical solution of the embodiments of the present disclosure, the drawings which are to be used in the description of the embodiments of the present disclosure will be briefly described. It will be apparent that the drawings in the following description are merely examples of the present disclosure. Those skilled in the art may obtain other drawings from these drawings without paying creative work.

FIG. 1 is a schematic diagram illustrating producing a via with a mask in the related art;

FIG. 2 is a top view of a mask in the related art;

FIG. 3 is a schematic diagram illustrating producing a via with a mask according to an embodiment of the present disclosure;

FIG. 4 is a schematic diagram illustrating a transmitted light being diffracted in a mask according to an embodiment of the present disclosure;

FIG. 5 is a graph illustrating comparison between exposure intensity of the mask according to an embodiment of the present disclosure and the mask in the related art;

FIG. 6 is a side view of a mask according to an embodiment of the present disclosure;

FIG. 7 is a side view of another mask according to an embodiment of the present disclosure;

FIG. 8A-8B are top views of a mask according to a first embodiment of the present disclosure;

FIG. 9A-9B are top views of a mask according to a second embodiment of the present disclosure; and

FIG. 10A-10B are top views of a mask according to a third embodiment of the present disclosure.

### DETAILED DESCRIPTION

The embodiments of the present disclosure will now be described in conjunction with the accompanying drawings of the embodiments of the present disclosure. It will be apparent that the described embodiments are part of the embodiments of the present disclosure and not all of the embodiments. Based on the embodiments of the present disclosure, all other embodiments obtained by those skilled in the art without making creative work are within the scope of the protective scope of the present disclosure.

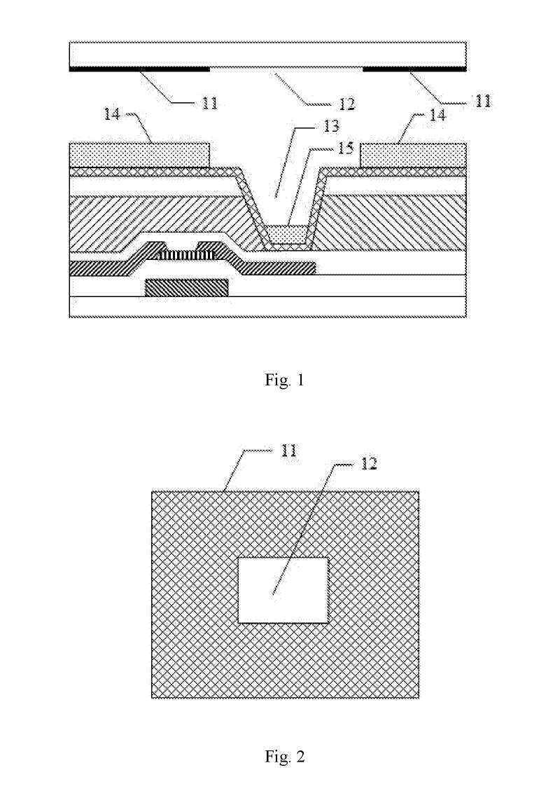

FIGS. 1 and 2 are respectively a schematic diagram illustrating producing a via with a mask in the related art and a top view of a mask in the related art. As shown FIGS. 1 and 2, the mask includes a light shielding region 11 and a light transmitting region 12. The photoresist 14 of the other portion of the substrate corresponding to the light shielding region 11 will not be irradiated with light. Therefore, these photoresists 14 are retained. The light transmitting region 12 corresponds to the via 13. The light passes through the light transmitting region 12 and irradiates the photoresist in the via 13. After the irradiation, the photoresist may be removed by etching. Due to the above-mentioned defects, residual photoresist 15 may appear at the via 13, such that the via 13 cannot be resolved, affecting the product yield.

In order to solve this problem, the present disclosure provides the following mask.

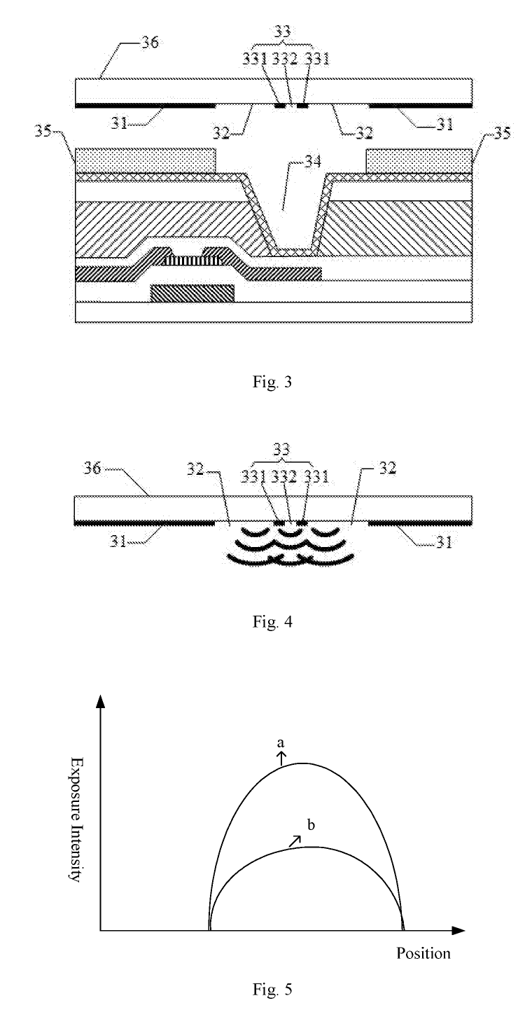

An embodiment of the present disclosure provides a mask. FIG. 3 is a schematic diagram illustrating producing a via with a mask according to an embodiment of the present disclosure. As shown in FIG. 3, the mask includes a light shielding region 31, a light transmitting region 32, and a diffraction region 33. Specifically, the light shielding region 31, the light transmitting region 32 and the diffraction region 33 may be provided on the surface of the substrate 36. The substrate 36 is a transparent material, generally being quartz glass. The light shielding region 31 may surround the light transmitting region 32 (as shown in FIG. 3), or the light shielding region 31 may be surrounded by the light transmitting region 32, depending on the shape of the via 34 to be formed. The light shielding region 31 blocks the light so as not to change the characteristics of the photoresist 35 at that position, and thus the photoresist 35 at the position of the substrate corresponding to the light shielding region 31 will not be removed. The light shielding region 31 may be formed by providing a black material on the surface of the substrate 36. The black material may be Cr, CrO2 and other black light shielding metal or metal oxide. The light transmitting region 32 corresponds to the via 34. The light transmitting region 32 may be formed by not providing a black material on the surface of the substrate 36. The shape of the light transmitting region 32 is generally determined by the shape of the via 34. The light may pass through the light transmitting region 32 to irradiate the photoresist at the via 34 to expose the photoresist here to the light, such that this portion of the photoresist may be etched away. In general, the center of the light transmitting region 32 faces directly the center of the via 34 such that the transmitted light may be irradiated to the entire area of the via 34. The diffraction region 33 is provided in the light transmission region 32 for diffracting the transmitted light. FIG. 4 is a schematic diagram illustrating a transmitted light being diffracted in a mask according to an embodiment of the present disclosure.

By using a mask to diffract the transmitted light, it may enhance the exposure intensity, and may effectively change the properties of the photoresist to be irradiated, such that the problem of residual photoresist in the related art may be avoided. The resolution of the via 34 may be improved, thus improving the product yield. FIG. 5 is a graph illustrating comparison between exposure intensity of the mask according to an embodiment of the present disclosure and the mask in the related art. As shown in FIG. 5, the abscissa indicates positions corresponding to the regions of the mask in FIG. 3. The position where the exposure intensity is the largest is the center of the light transmission region 32. As shown in the Figure, a represents the exposure intensity of the mask according to the embodiment of the present disclosure, and b represents the exposure intensity of the mask in the related art. As may be seen from FIG. 5, the exposure intensity of the mask according to the embodiment of the present disclosure is larger than that of the mask in the related art. As shown in FIG. 3, after the mask of the present embodiment is applied, no residual photoresist appears at the via 34.

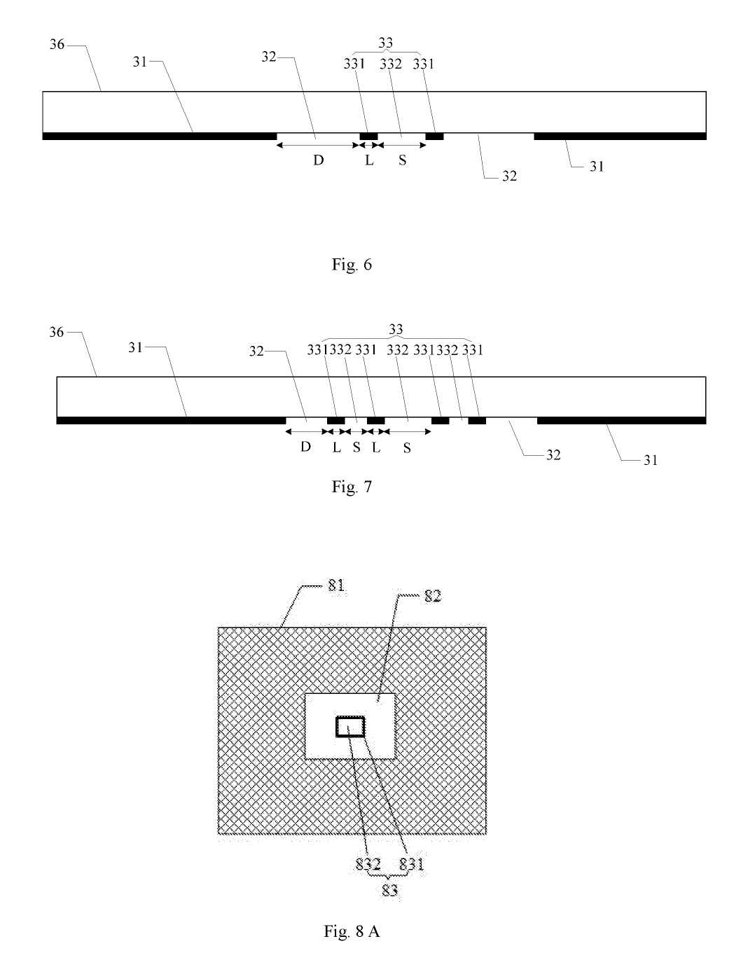

Specifically, as shown in FIGS. 6 and 7, the diffraction region 33 includes at least one light shielding portion 331 and at least one light transmitting portion 332. The light shielding portion 331 may be formed by providing a black material on the surface of the substrate 36. The light transmitting portion 332 may be formed by not providing a black material on the surface of the substrate 36. The distance S between the opposite sides of the light transmitting portion 332 is 0.21 μm to 0.5 μm. The light transmission portion 332 of the specific size may improve the diffraction effect. The distance S between the opposite sides of the plurality of light transmitting portions 332 may be the same or different.

In one embodiment, the shape of the light shielding portion 331 may be a ring shape, a bar shape, or the like. The width L of the light shielding portion 331 is 0.2 μm to 0.5 μm. The light shielding portion 331 of the specific size, cooperated with the light transmission portion 332 of a specific size, may further improve the diffraction effect. The width L of the plurality of light shielding portions 331 may be the same or different.

In one embodiment, the distance D between the edge of the light transmitting region 32 and the adjacent light shielding portion 331 is 1 μm to 2 μm. The specific distance may further improve the diffraction effect.

The mask of the present disclosure will be further described below with reference to specific embodiments.

### First Embodiment

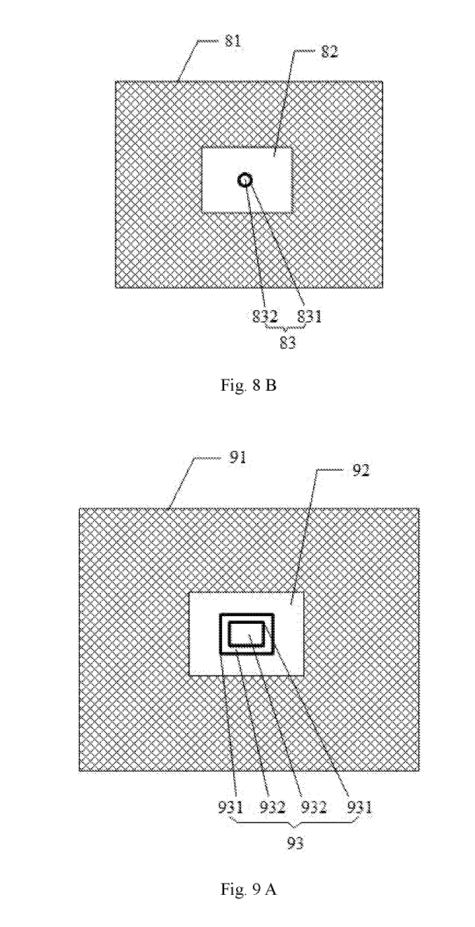

FIG. 8A-8B are top views of a mask according to a first embodiment of the present disclosure. The structure of the mask according to the first embodiment is the same as that of the above-described mask of the present disclosure, and includes a light shielding region 81, a light transmitting region 82, and a diffraction region 83. The diffraction region 83 includes a light shielding portion 831 and a light transmitting portion 832.

The number of the light shielding portion 831 is one. Therefore, in order to form the diffraction region 83, the light shielding portion 831 of the diffraction region 83 is in a ring shape. The ring shape may be a circular ring, a square ring, a rectangular ring, or the like. As shown in FIG. 8A, the ring shape is a rectangular ring; and as shown in FIG. 8B, the ring shape is a circular ring. The light transmitting portion 832 is an area surrounded by a ring-shaped light shielding portion 831.

In view that the center of the light transmitting region 82 generally overlaps with the center of the via and the photoresist at the bottom of the via tends to remain, in one implementation, the center of the light transmitting portion 832 overlaps with the center of the light transmitting region 82 such that the center of the light transmitting portion 832 overlaps with the center of the via. Then, after diffraction, the transmitted light irritates the photoresist in the entire area of the via, particularly the photoresist at the bottom of the via, such that the photoresist at the via may be effectively removed.

### Second Embodiment

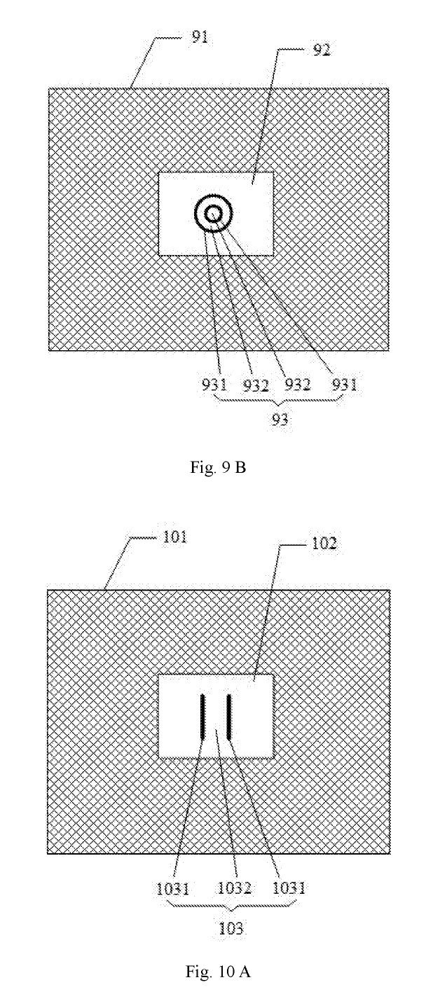

FIG. 9A-9B are top views of a mask according to a second embodiment of the present disclosure. The structure of the mask according to the second embodiment is the same as that of the above-described mask, and includes a light shielding region 91, a light transmitting region 92, and a diffraction region 93. The diffraction region 93 includes light shielding portions 931 and light transmitting portions 932.

The number of the light shielding portions 931 is two or more, and the number of the light shielding portions 931 shown in FIG. 9 is two. The light shielding portion 931 is in a ring shape. The ring shape may be a circular ring, a square ring, a rectangular ring, or the like. Two or more ring-shaped light shielding portions 931 are arranged as one surrounded by another successively. As shown in FIG. 9A, the ring shape is a rectangular ring; and as shown in FIG. 9B, the ring is a circular ring. The light transmitting portions 932 includes an area surrounded by the ring-shaped light shielding portion 931 of the innermost ring and areas between two adjacent ring-shaped light shielding portions 931.

In view that the center of the light transmitting region 92 generally overlaps with the center of the via and the photoresist at the bottom of the via tends to remain, in one implementation, the center of the light transmitting portion 932 surrounded by the ring-shaped light shielding portion 931 of the innermost ring overlaps with the center of the light transmitting region 92. Then, after diffraction, the transmitted light irritates the photoresist in the entire area of the via, particularly the photoresist at the bottom of the via, such that the photoresist at the via may be effectively removed.

In one implementation, two or more ring-shaped light shielding portions 931 are arranged concentrically so as to cause the transmitted light, after diffraction, to uniformly irradiate the entire area of the via such that the exposure intensity of the different regions of the via may be uniform.

### Third Embodiment

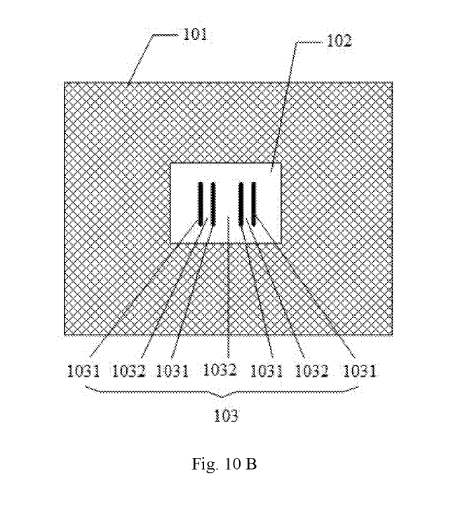

FIG. 10A-10B are top views of a mask according to a third embodiment of the present disclosure. The structure of the mask according to the third embodiment is the same as that of the above-described mask of the present disclosure, and includes a light shielding region 101, a light transmitting region 102, and a diffraction region 103. The diffraction region 103 includes light shielding portions 1031 and light transmitting portions 1032.

The number of the light shielding portions 1031 is two or more. As shown 10A, the number of the light shielding portions 1031 is two. As shown 10B, the number of the light shielding portions 1031 is four. The light shielding portion 1031 is a bar shape. The two or more shading portions 1031 are arranged in parallel to each other. The light transmitting portion 1032 is an area between two adjacent light shielding portions 1031.

In view that the center of the light transmitting region 102 generally overlaps with the center of the via and the photoresist at the bottom of the via tends to remain, in one implementation, the number of the light shielding portions 1031 is an even number, and the number of the light transmitting portions 1032 is an odd number, such that the center of the innermost light transmitting portion 1032 overlaps with the center of the light transmitting region 102. Then, after diffraction, the transmitted light irritates the photoresist in the entire area of the via, particularly the photoresist at the bottom of the via, such that the photoresist at the via may be effectively removed.

Accordingly, with the mask of the embodiments of the present disclosure, by using a mask to diffract the transmitted light, it may enhance the exposure intensity at the via, and may effectively remove the residual photoresist at the via. The resolution of the via may be improved, thus improving the product yield.

Each of the embodiments in this specification is described in a progressive manner, each of which is illustrated by focusing on differences from other embodiments, and portions similar to those of the various embodiments may be referred to each other.

Although the preferred embodiments of the embodiments of the present disclosure have been described, those skilled in the art will be able to make further changes and modifications to these embodiments based on the basic inventive concept thereof. Therefore, the appended claims are intended to be construed as including the preferred embodiments and all changes and modifications that fall within the scope of the present disclosure.

Last but not least, it should also be noted that, in this context, relational terms such as first and second are used only to distinguish an entity or operation from another entity or operation without necessarily requiring or implying that there is any such actual relationship or sequence between these entities or operations. Moreover, the term “comprising”, or “including”, or any other variant thereof is intended to encompass a non-exclusive inclusion such that a process, method, an article, or a terminal device that includes a series of elements includes not only those elements but also a other elements that are inherent to this process, method, article, or terminal device. In the absence of more limitations, the elements defined by the statement “including one . . . ” do not preclude the presence of additional elements in the process, method, article, or terminal device that includes the elements.

Described above are only specific embodiments of the present disclosure, which are not exclusive. Any modification or replacement within the technical scope disclosed herein which is readily conceived by those skilled in the art is intended to be within the scope of the present disclosure. Therefore, the scope of protection of the present disclosure is subject to the scope of protection of the claims.

What is claimed is:

1. A mask, comprising
a light shielding region,
a light transmitting region, and
a diffraction region,
disposed in the light transmission region for diffracting transmitted light.

2. The mask according to claim 1, wherein the diffraction region comprises at least one light shielding portion and at least one light transmitting portion, and a distance between opposite sides of the light transmitting portion is 0.2 μm to 0.5 μm.

3. The mask according to claim 2, wherein a width of the light shielding portion is 0.2 μm to 0.5 μm.

4. The mask according to claim 2, wherein a number of the light shielding portion is one, and the light shielding portion is in a ring shape, the light shielding portion is an area surrounded by the ring-shaped light shielding portion.

5. The mask according to claim 4, wherein a center of the light transmitting portion overlaps with a center of the light transmitting region.

6. The mask according to claim 2, wherein a number of the light shielding portion is two or more, and the light shielding portion is in a ring shape, the two or more ring-shaped light shielding portions are arranged as one surrounded by another successively, and light shielding portion comprises an area surrounded by the ring-shaped light shielding portion of the innermost ring and areas between two adjacent ring-shaped light shielding portions.

7. The mask according to claim 6, wherein the center of the light transmitting portion surrounded by the ring-shaped light shielding portion of the innermost ring overlaps with the center of the light transmitting region.

8. The mask according to claim 6, wherein two or more ring-shaped light shielding portions are arranged concentrically.

9. The mask according to claim 6, wherein the ring shape is a circular ring, a square ring, or a rectangular ring.

10. The mask according to claim 7, wherein the ring shape is a circular ring, a square ring, or a rectangular ring.

11. The mask according to claim 8, wherein the ring shape is a circular ring, a square ring, or a rectangular ring.

12. The mask according to claim 2, wherein a number of the light shielding portion is two or more, and the light shielding portion is in a bar shape, the two or more shading portions are arranged in parallel to each other, and the light transmitting portion is an area between two adjacent light shielding portions.

13. The mask according to claim 12, wherein the number of the light shielding portions is an even number and the number of the light transmitting portions is an odd number, the center of the innermost light transmitting portion overlaps with the center of the light transmitting region.

14. The mask according to claim 2, wherein a distance between the edge of the light transmitting region and the adjacent light shielding portion is 1 μm to 2 μm.
